(19) United States
(12) Patent Application Publication
(10) Pub. No.: US 2024/0335831 A1
(43) Pub. Date: Oct. 10, 2024

(54) OPTICAL ELEMENT AND REACTION CHAMBER

(71) Applicant: MAX-PLANCK-GESELLSCHAFT ZUR FÖRDERUNG DER WISSENSCHAFTEN E.V., München (DE)

(72) Inventor: Wolfgang BRAUN, Bietigheim-Bissingen (DE)

(21) Appl. No.: 18/294,903

(22) PCT Filed: Aug. 6, 2021
(86) PCT No.: PCT/EP2021/072025

§ 371 Date: Feb. 2, 2024

(51) Int. Cl. B01L 3/00

(52) U.S. Cl. CPC B01L 3/502715; B01L 2200/025; B01L 2200/0689; B01L 2300/0654; B01L 2300/0851; B01L 2300/168

(57) ABSTRACT

The present invention relates to an optical element (10) for use with a reaction chamber (70), in particular a reaction chamber (70) of a thermal laser evaporation system, the reaction chamber (70) having a chamber wall (72), with a flange (80) of the reaction chamber (70) being arranged at an opening (74) in the chamber wall (72). Further, the present invention relates to a reaction chamber (70), in particular reaction chamber (70) of a thermal laser evaporation system, comprising a chamber wall (72) enclosing a sealable reaction volume, in particular sealable with respect to the ambient atmosphere, the reaction volume fillable with a reaction atmosphere (90), the reaction chamber (70) further comprising a flange (80) arranged at an opening (74) in the chamber wall (72).

The present invention relates to an optical element for use with a reaction chamber, in particular a reaction chamber of a thermal laser evaporation system, the reaction chamber having a chamber wall, with a flange of the reaction chamber being arranged at an opening in the reaction chamber wall. Further, the invention relates to a reaction chamber, in particular to a reaction chamber of a thermal laser evaporation system, comprising a chamber wall for enclosing a sealable reaction volume, in particular sealable with respect to the ambient atmosphere, the reaction volume fillable with a reaction atmosphere, the reaction chamber further comprising a flange arranged at an opening in the chamber wall.

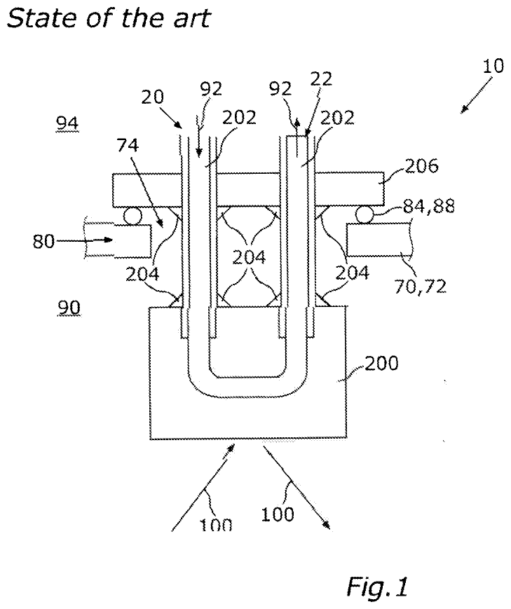

Applications such as in thermal laser epitaxy or synchrotron x-ray optics require active optical surfaces for mirrors, Bragg mirrors, absorbers and similar applications. In FIG. 1, such an optical element 10 of the state of the art arranged at a flange 80 of a reaction chamber 70 is depicted. An optical element 10 is arranged at an opening 74 of the chamber wall 72.

As depicted, for the optical elements 10 according to the state of the art the reflector section 200 for reflecting or absorbing the electromagnetic radiation 100 is made from a first material, whereas the cooling tubes 202 and the seal section 206 are made from different materials. In the depicted embodiment, the seal section 206 forms an elastomer seal, in which an elastomer ring seal 84, 88 seals the reaction volume containing the reaction atmosphere 90 from the outside of the reaction chamber 70, where ambient atmosphere 94 is present.

The aforementioned usage of different materials for the reflector section 200, the cooling tubes 22 and the seal section 206 causes the requirements of fixations of these elements with respect to each other, in the depicted embodiment provided by welds 204. However, these joints between dissimilar materials such as for instance silicon and copper, tend to leak under the high thermal stresses imposed by high-power operation, and therefore require expensive non-standard solutions. In addition, due to the welds 204, there is usually no precise mechanical alignment between the seal section 206 and the reflector section 200, and additional measures need to be taken to align the reflector section 200 within the reaction chamber 70.

In view of the above, it is an object of the present invention to provide an improved optical element for use with a reaction chamber and an improved reaction chamber which do not have the aforementioned drawbacks of the state of the art. In particular, it is an object of the present invention to provide an improved optical element for use with a reaction chamber and an improved reaction chamber, which allow an especially easy arrangement and in particular alignment of an optical surface of the optical element in an arranged state within the reaction chamber and simultaneously the secure sealing of a flange of the reaction chamber, at which the optical element is arrangeable or arranged, respectively.

This object is satisfied by the respective independent patent claims. In particular, this object is satisfied by an optical element for use with a reaction chamber according to independent claim 1 and by a reaction chamber according to independent claim 23. The dependent claims describe preferred embodiments of the invention. Details and advantages described with respect to an optical element according to the first aspect of the invention also refer to a reaction chamber according to the second aspect of the invention, and vice versa, if of technical sense.

According to the first aspect of the invention, the object is satisfied by an optical element for use with a reaction chamber, in particular a reaction chamber for a thermal laser evaporation system, the reaction chamber having a chamber wall, with a flange of the reaction chamber being arranged at an opening in the chamber wall.

The optical element according to the first aspect of the invention especially comprises a one-piece body with an ambient end and a chamber end arranged opposite to each other along a central body axis, whereby in an assembled state of the optical element the ambient end is arranged outside of the reaction chamber and the chamber end is arranged within the reaction chamber. Further, the ambient end of the body comprises a sealing means for sealing the flange of the reaction chamber, and the chamber end comprises an optical surface for reflecting and/or shaping and/or absorbing electromagnetic radiation within the reaction chamber.

The optical element according to the first aspect of the present invention can be used with a reaction chamber, in particular at a flange surrounding an opening in a chamber wall of the reaction chamber. The chamber wall of the reaction chamber encloses a reaction volume sealable with respect to the ambient atmosphere and fillable with a reaction atmosphere. The reaction atmosphere can be a vacuum between 10-4 and 10-12 hPa, or can comprise or consist of one or more reaction gases such as for instance molecular oxygen, ozone, molecular hydrogen or molecular nitrogen, with a pressure of 10-8 hPa to ambient pressure, respectively up to 1 hPa. Further, the reaction gas can at least partly be ionized, in particular ionized by plasma ionization.

According to the present invention, the core of the optical element is formed by a one-piece body. In other words, said one-peace body consists of a single material and in particular extends between an ambient end and a chamber end, whereby the ambient end carries a sealing means and the chamber end carries an optical surface. In particular, in an assembled state of the optical element according to the first aspect of the present invention, the ambient end of the optical element is arranged outside of the reaction chamber and the chamber end is arranged within the reaction chamber and hence within the reaction volume.

The sealing means comprised by the ambient end provides sealing the opening in the chamber wall by cooperation with respective means of the flange. Hence, the reaction atmosphere is contained within the reaction chamber and the atmosphere present at the ambient end, in most of the cased the ambient atmosphere, but not limited to this, is safely locked out.

The optical surface comprised by the chamber end is accordingly constructed for the intended purpose, namely for reflecting and/or shaping and/or absorbing an electromagnetic radiation within the reaction chamber. An electromagnetic radiation according to the present invention can preferably be provided as laser radiation, and/or comprise a wavelength in the UV and/or visual and/or IR range. However, this list is not limiting and for instance also x-rays or microwaves are electromagnetic radiation in the scope of the present invention. Said construction of the optical surface can comprise coatings for enhancing a reflectivity or absorptivity of the optical surface and/or surface treatments such as polishing or roughening.

In particular, aforementioned ambient end and chamber end are opposing parts of a single one-piece body. In other words, for the optical element according to the first aspect of the present invention, an assembling of different elements solving different tasks like sealing or providing optical properties is not needed.

Further, as the respective positions and orientations of the ambient end and the chamber end, respectively, are fixed with respect to each other, after fixing and aligning the sealing means provided by the ambient end at the flange of the reaction chamber, also the position and orientation of the optical surface provided by the chamber end are determined. As a result, an additional alignment of the optical surface carried by the chamber end is not needed or at least significantly simplified.

In summary, by providing the optical element according to the first aspect of the present invention with a one-piece body, both tasks, namely sealing the reaction chamber and arranging and aligning an optical surface within the reaction chamber, can be simplified. Simultaneously, no drawbacks or disadvantages with respect to tightness and precision of the alignment are to be feared.

Further, the optical element according to the first aspect of the present invention can be characterized in that the body consists of aluminum or of an aluminum alloy or of copper or of a copper alloy. Both elements, aluminum and copper, respectively, comprise a very high reflectivity for electromagnetic radiation. Further, also both materials comprise a high thermal conductivity, allowing operations with high intensity electromagnetic radiations. Simultaneously, both materials are suitable for usage in high purity environments such as reaction atmospheres provided as vacuum with a pressure of 10-8 hPa to 10-12 hPa. Using an alloy of one of the materials allows to keep aforementioned advantages and enhancing other features, such as for instance structural stability and/or thermal conductivity. Possible aluminum alloys are for instance EN AW 6082 T6, which is an especially high-strength aluminum alloy, or EN AW 6063, which is an aluminum alloy with a high thermal conductivity of above 200 W/mK.

In addition, the optical element according to the first aspect of the present invention can comprise that the sealing means forms a part of a knife-edge type seal, in particular a circumferential knife-edge and/or a circumferential receptacle for a ring seal, preferably for a metallic ring seal, and/or one or more circumferential sealing surfaces. Preferably, standardized sealing systems such as ISO 3669 may be used. In particular for a vacuum used as reaction atmosphere, especially for a high vacuum with a pressure of 108 hPa to 10-12 hPa, knife-edge type seals are most suitable. By providing parts, in particular all necessary parts, of such a knife-edge type seal, the secure usage of said high vacuum as reaction atmosphere can be rendered possible.

Alternatively, the optical element according to the first aspect of the present invention can be characterized in that the sealing means forms a part of an elastomer seal, in particular a circumferential receptacle for an elastomer ring seal, preferably an O-ring, and/or one or more circumferential sealing surfaces. Such elastomer seals are one of the most common types of seals used with reaction chambers. By providing parts, in particular all necessary parts, of such an elastomer seal, the usage of the optical element according to the first aspect of the present invention with a vast variety of reaction chambers can be provided.

According to another embodiment of the optical element according to the first aspect of the present invention, the chamber end comprises a planar surface forming at least a part of the optical surface for specularly reflecting an impinging electromagnetic radiation. In other words, in this embodiment the respective part of the optical element acts as a plane mirror for the electromagnetic radiation, for instance for a beam guidance of the electromagnetic radiation within the reaction chamber. Hence, a precise guidance with no or at least no essential dispersion and widening of the electromagnetic radiation within the reaction chamber can be provided.

Additionally, or alternatively, the optical element according to the first aspect of the present invention can also be characterized in that the chamber end comprises a curved surface forming at least a part of the optical surface for reflecting and simultaneously shaping, preferably focusing and/or defocusing, an impinging electromagnetic radiation. In other words, in this embodiment the respective part of the optical element acts as a shaping element for the electromagnetic radiation, for instance for a beam guidance of the electromagnetic radiation within the reaction chamber. Hence, a precise shaping, in particular a focusing or defocusing, of the electromagnetic radiation within the reaction chamber can be provided.

According to a further enhanced embodiment of the optical element according to the first aspect of the present invention, the planar surface and/or the curved surface consists of a bare surface of the body, preferably of a polished bare surface of the body. As mentioned above, in particular aluminum and copper already comprise a high reflectivity for electromagnetic radiation. Hence, already a bare surface of the one-piece body of the optical element according to the first aspect of the present invention can provide a good or even excellent reflectivity. By polishing, for instance with diamond tools, said bare surface, the respective reflectivity can be enhanced even further.

As an alternative, the optical element according to the first aspect of the present invention can also comprise that the planar surface and/or the curved surface are coated with an active optical coating chosen for the intended electromagnetic radiation to be reflected, whereby the active optical coating comprises in particular a metal coating and/or a coating for forming a Bragg mirror as optical surface. With a metal coating the reflectivity of the optical surface can be improved for a wide wavelength range, whereas a Bragg mirror enhances the reflectivity only in a very narrow wavelength range and hence also acts as filter element. In particular, the coating can comprise a single film or a multi-film structure. An adaptation of the optical surface for the special needs of the intended operation and/or electromagnetic radiation can thereby be provided.

In another alternative embodiment of the optical element according to the first aspect of the present invention, the chamber end comprises a roughened surface and/or a surface coated with an absorption coating for absorbing an impinging electromagnetic radiation. In this embodiment, the electromagnetic radiation impinging on the optical surface should not be reflected, but in contrast to that be absorbed. By providing a roughened surface and/or an absorption coating on the optical surface, this intended absorption can be enhanced. The roughening can be for instance be provided by sand and/or bead blasting the optical surface.

Electromagnetic radiation absorbed at the optical surface deposits its energy into the optical surface and hence into the body of the optical element according to the first aspect of the present invention. Hence, by measuring a temperature and/or temperature change of the body, the amount of energy absorbed from the electromagnetic radiation can be determined. In other words, the optical element according to the present invention can be used as a bolometer. Based on that, a monitoring of the electromagnetic radiation within the reaction chamber can be provided.

Further, the optical element according to the first aspect of the present invention can be enhanced by that the chamber end is slotted in two or more end segments by slots perpendicular to the body axis, whereby in particular the two or more end segments are arranged rotationally symmetrical around the body axis. In other words, the optical surface is divided into several parts, namely the end segments, whereby each of the end segments comprises one of said parts of the optical surface. As the slots form end segments at the optical surface distinct and separated from each other, the energy deposit from the absorbed electromagnetic radiation described in the paragraph above is also distributed over the end segments. By measuring a temperature and/or temperature change of each of the end segments, the amount of energy absorbed from the electromagnetic radiation in each of said end segments can be separately determined. Based on that, a monitoring of the electromagnetic radiation within the reaction chamber can be provided with an improved spatial resolution.

Preferably, the optical element according to the first aspect of the present invention is further enhanced by that the slots extend 5% to 50% of the length of the body along the body axis from the chamber end towards the ambient end. On the one hand, slots with a large extension along the body axis provide end segments with an improved thermal insulation between them to provide spatial resolution with minimal crosstalk between the end segments with respect to the electromagnetic radiation. On the other hand, slots with a large extension along the body axis also weaken the structural stability of the one-piece body of the optical element. An extension of the slots of 5% to 50% of the length of the body along the body axis from the chamber end towards the ambient end is a good tradeoff for meeting both of the aforementioned boundary conditions.

Further, the optical element according to the first aspect of the present invention can be characterized in that the body comprises one or more continuous cooling ducts for a coolant fluid, wherein each cooling duct comprises an inlet opening and an outlet opening arranged at the ambient end of the body. By providing a cooling of the one-piece body, in particular the optical surface of the optical element according to the first aspect of the present invention can be temperature stabilized. In particular, as the optical element comprises as central part the one-piece body, this cooling can be provided without need for additional elements such as cooling pipes. Continuous conditions within the reaction chamber, both for reflecting and absorbing, respectively, of electromagnetic radiation at the optical element according to the first aspect of the present invention can thereby be provided.

Preferably the optical element according to the first aspect of the present invention can be enhanced by that the inlet opening and the outlet opening are threaded for an arrangement of screw-in terminals of supply lines of the coolant fluid. By providing threads, in particular standardized threads, a connection of the cooling ducts of the optical element according to the first aspect of the present invention to other elements of cooling systems can be provided more easily.

In particular, the optical element according to the first aspect of the present invention can comprise that the one or more cooling ducts are V-shaped, wherein from both the inlet opening and the outlet opening, respectively, a straight leg of the cooling duct extends into the body, whereby the two legs meet within the body. In other words, the two legs of the cooling duct can be easily manufactured as bores, in particular as deep hole drillings. The manufacture of a continuous cooling duct in the one-piece body can thereby be simplified.

The V-shaped cooling water channel has the additional advantage that the sharp turn of the cooling water at the tip of the cooling duct favors turbulent flow. Even for laminar coolant flow, the sharp turn results in an additional pressure of the cooling water towards the tip of the V-shaped cooling duct. Both effects lead to a vanishing or thin laminar layer and therefore increased cooling power at this position closest to the center of the optical surface, where for a Gaussian beam, the power density of the electromagnetic radiation is also highest. This increases the efficiency of the fluid cooling in this concept.

In addition, the optical element according to the first aspect of the present invention can be characterized in that if the optical surface is designed to reflect and/or shape the impinging electromagnetic radiation, the maximum extension of the cooling duct along the body axis is at least 60%, preferably 75%, most preferably 85% or more, of the extension of the body along the body axis from the ambient end towards the chamber end.

When used as a reflecting element, it is advantageous for the performance of the optical element that the temperature of the reflecting optical surface stays constant or at least essentially constant, and in particular as close as possible to the temperature of the coolant fluid. By providing a cooling duct which ends in the vicinity of or at least near to the optical surface, which can be achieved by ensuring that the maximum extension of the cooling duct along the body axis is at least 60%, preferably 75%, most preferably 85% or more, an optimal cooling of the optical surface and hence the aforementioned constant or at least essentially constant and in particular low temperature of the optical surface can be provided.

According to an alternative embodiment of the optical element according to the first aspect of the present invention, if the optical surface is designed to absorb an impinging electromagnetic radiation, the maximum extension of the cooling duct along the body axis is between 20% and 65%, preferably between 35% and 55%, of the extension of the body along the body axis from the ambient end towards the chamber end.

In contrast to the embodiment described in the previous paragraph, when used as an absorbing element, it is advantageous for the performance of the optical element that absorbing capacity and the absorbing volume of the optical element is sufficient for absorbing the impinging electromagnetic radiation. In particular, if the temperature or temperature change of the absorbing region of the one-piece body is measured for monitoring the electromagnetic radiation, a too extensive cooling of said absorption region would be disturbing or even counterproductive. In such a bolometer arrangement, the measured temperature is a function of the absorbed power due to the finite heat conduction between the measurement point near the absorbing surface and the cooling duct. A larger separation of the measurement point and the cooling duct, or a reduced thermal conductivity by, e.g., reducing the cross-section of the body material between the measurement point and the cooling duct, therefore increase the temperature range for a given absorbed power range, and therefore the sensitivity of the measurement. In addition, also by choosing the coolant fluid temperature accordingly, an improved and optimized range of temperature measurement matching a given temperature range of a temperature sensor, may be provided.

Hence, by choosing a cooling duct with a maximum extension of the cooling duct along the body axis between 20% and 65%, preferably between 35% and 55%, of the extension of the body along the body axis from the ambient end towards the chamber end, it can be ensured that on the one hand a sufficient cooling of the one-piece body of the optical element can be provided without on the other hand disturbing the measurement of an energy deposited by the absorbed electromagnetic radiation. In other words, in this embodiment the optical element according to the present invention can act as bolometer for measuring the energy of the absorbed electromagnetic radiation.

Preferably, the optical element according to the first aspect of the present invention can be enhanced further by that the one or more cooling ducts are equipped with means for measuring a flow of the coolant fluid, and/or with means for measuring an absolute temperature of the coolant fluid, and/or with means for measuring a temperature change of the coolant fluid between the inlet opening and the outlet opening. In this embodiment, the cooling of the optical element itself is used for measuring an amount of the energy deposited into the one-piece body of the optical element. In particular, as the cooling is intended for removing or taking away the deposited energy, this is indeed an indirect way but nevertheless a very accurate and quantitative way of measuring an amount of energy deposited by the impinging electromagnetic radiation, in particular if, additionally to the temperature difference between inlet and outlet, also the flow per unit time of the coolant fluid is measured.

Another alternative or additional embodiment of the optical element according to the first aspect of the present invention can comprise that the body comprises one or more bores for arranging a means for measuring a temperature of the body, in particular a thermocouple, wherein the one or more bores start at the ambient end of the body and end within the body along the body axis at least at 75%, preferably at 85%, most preferably at 95% or more, of the extension of the body along the body axis from the ambient end towards the chamber end.

In contrast to the embodiment described in the previous paragraph, in this embodiment a direct measurement of the temperature or of a temperature change of the one-piece body caused by the impinging electromagnetic radiation can be provided. For this, the means for measuring the temperature should be placed in the vicinity or at least near to the optical surface. By providing bores which start at the ambient end of the body and end within the body along the body axis at least at 75%, preferably at 85%, most preferably at 95% or more, of the extension of the body along the body axis from the ambient end towards the chamber end, this requirement can be met especially easily.

According to a special embodiment of the optical element according to the first aspect of the present invention, the body comprises a bore for each of the end segments, wherein the respective bore ends within the respective end segment. As described above, said end segments can be used for providing or enhancing a spatial resolution for the monitoring of the electromagnetic radiation impinging on the optical surface. For that, a measurement of the deposited energy for each of the end segments is of great advantage. Providing for each end segment a dedicated bore which ends in the respective segment is a simple but nevertheless effective way for enabling the aforementioned measurement.

Further, the optical element according to the first aspect of the present invention can comprise that the body comprises attachment means on its chamber end for attaching and/or fixing additional components within the reaction chamber. In other words, additionally to its use as optical component for reflecting and/or absorbing electromagnetic radiation, the optical element according to the first aspect of the present invention can also be used as platform for additional components. In particular, the precise alignment of the one-piece body and the optical surface, respectively, of the optical element according to the first aspect of the present invention can also be provided for the additional component attached and/or fixed to the attachment means of the optical element.

In addition, the optical element according to the first aspect of the present invention can be characterized in that the body comprises one or more feedthroughs for providing electrical connections and/or fluid connections from the ambient end to the chamber end. The optical element according to the first aspect of the present invention is used to seal an opening in the chamber wall of the reaction chamber. Such openings can also be used for providing feedthroughs for electrical connections and/or fluid connections between the reaction volume and the outside of the reaction chamber. By providing said feedthrough by the optical element according to the first aspect of the present invention, a number of additional openings in the chamber wall of the reaction chamber can be reduced and/or other openings can be used for other purposes.

According to a preferred enhancement of the optical element according to the first aspect of the present invention, the one or more feedthroughs end at the attachment means for providing electrical connections and/or fluid connections for the additional component arrangeable and/or fixable at the attachment means. The additional component attached and/or fixed to the attachment means of the optical element according to the first aspect of the present invention may need electrical connections and/or fluid connections for its operations. By providing the respective feedthroughs also as part of the optical element, the setup of the additional component and hence of the reaction chamber as a whole can be simplified.

According to a second aspect of the present invention the object is satisfied by a reaction chamber, in particular a reaction chamber of a thermal laser evaporation system, comprising a chamber wall enclosing a sealable reaction volume, in particular sealable with respect to the ambient atmosphere, the reaction volume fillable with a reaction atmosphere, the reaction chamber further comprising a flange arranged at an opening in the chamber wall. The reaction chamber according to the second aspect of the present invention is characterized in that an optical element according to the first aspect of the present invention is arranged at the flange and seals the opening in the chamber wall.

The reaction chamber according to the second aspect of the present invention comprises the optical element according to the first aspect of the present invention. Hence the reaction chamber according to the second aspect of the present invention can provide all advantages described above with respect to the optical element according to the first aspect of the present invention.

During the operation, in particular in a reaction chamber used in a thermal laser evaporation system, the optical surface may be coated by material evaporated and/or sublimated in the reaction chamber. Hence, the optical properties of the optical element may be altered, in particular worsened. Hence, as the optical element according to the first aspect of the present invention is arranged at a flange of the reaction chamber according to the second aspect of the present invention, as a particular advantage, the optical element can be replaced by another, preferably identical, optical element according to the first aspect of the present invention.

Further, the reaction chamber according to the second aspect of the present invention can comprise that the flange comprises a flange rim for arranging the optical element, whereby the flange rim is connected by a bellow to the chamber wall. In other words, the flange rim, and hence the optical element according to the first aspect of the present invention arranged at the flange rim, can be moved slightly as the bellow can be locally compressed or stretched. A precise alignment and/or a correction of an alignment of the optical element according to the first aspect of the present invention and hence of the optical surface within the reaction chamber can thereby be provided.

Additionally, the reaction chamber according to the second aspect of the present invention can be enhanced by that the reaction chamber, in particular the flange and/or the optical element, comprises a means for adjusting the relative position of the optical surface of the optical element within the reaction chamber by moving the optical element within the radius of movement provided by the bellow. Such adjustment means can be for instance manually driven and/or can comprise one or more actuators. The aforementioned precise alignment and/or a correction of an alignment of the optical surface can thereby be provided more simply. In addition, the adjustment means can preferably comprise a fixing device for fixing a completed adjustment.

The invention will be explained in detail in the following by means of embodiments and with reference to the drawings in which are shown:

FIG. 1A schematic side view of an optical element arranged at a reaction chamber according to the state of the art,

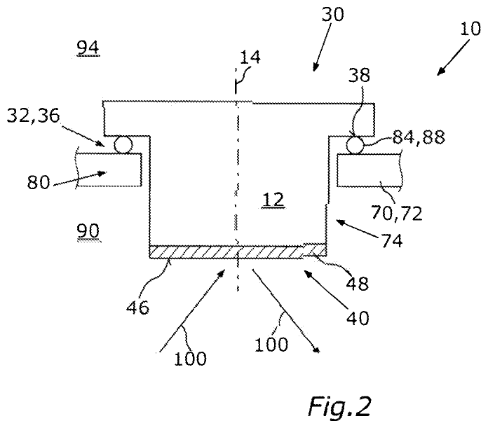

FIG. 2A schematic side view of a first embodiment of an optical element arranged at a reaction chamber according to the present invention,

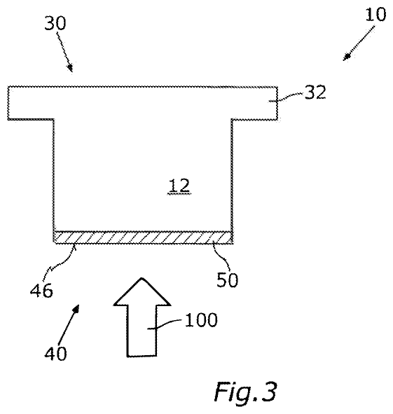

FIG. 3A schematic side view of a second embodiment of an optical element according to the present invention,

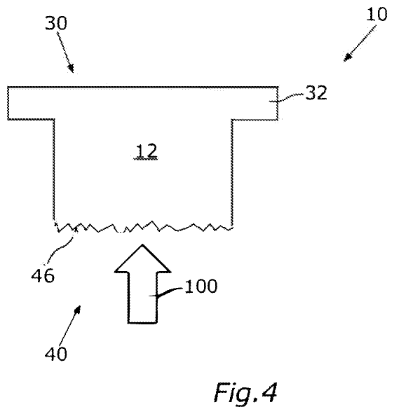

FIG. 4A schematic side view of a third embodiment of an optical element according to the present invention,

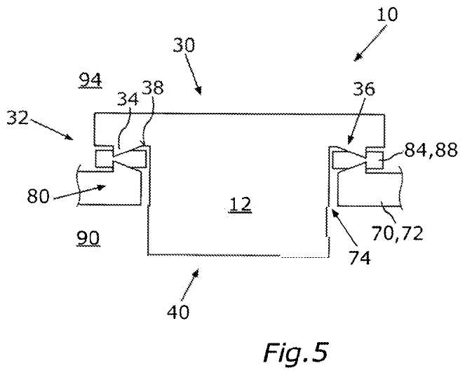

FIG. 5A schematic side view of a fourth embodiment of an optical element arranged at a reaction chamber according to the present invention,

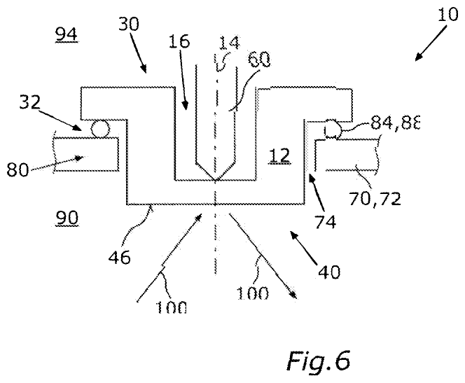

FIG. 6A schematic side view of a fifth embodiment of an optical element arranged at a reaction chamber according to the present invention,

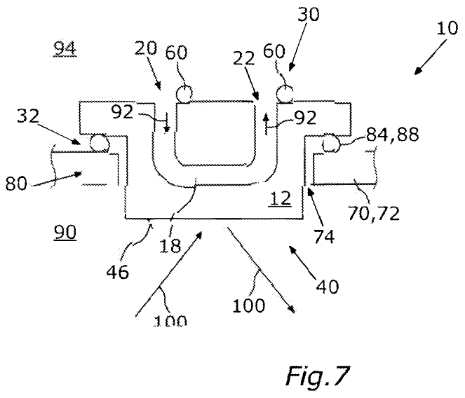

FIG. 7A schematic side view of a sixth embodiment of an optical element arranged at a reaction chamber according to the present invention,

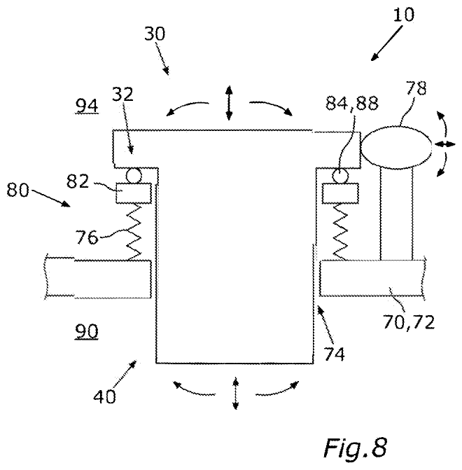

FIG. 8A schematic side view of a seventh embodiment of an optical element arranged at a reaction chamber according to the present invention,

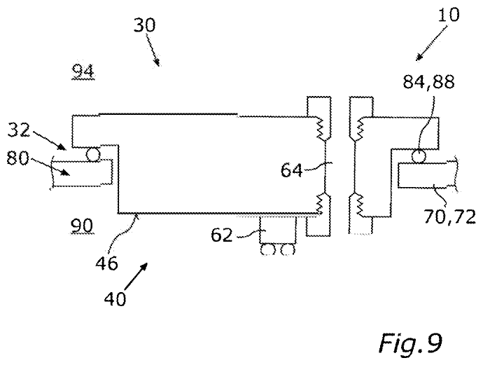

FIG. 9A schematic side view of an eighth embodiment of an optical element arranged at a reaction chamber according to the present invention,

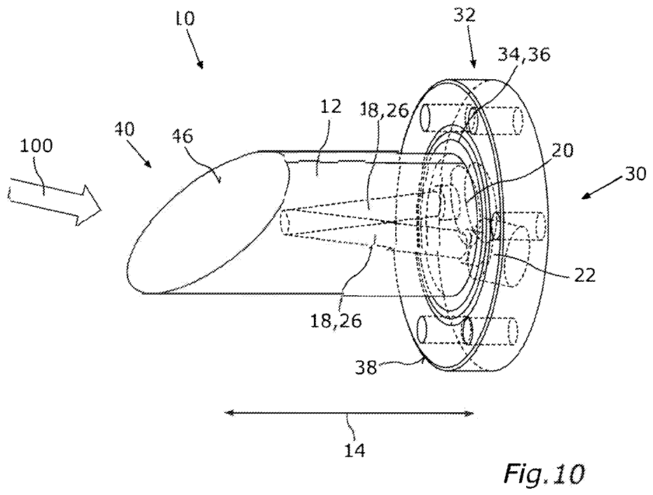

FIG. 10A semitransparent angled view of a ninth embodiment of an optical element according to the present invention,

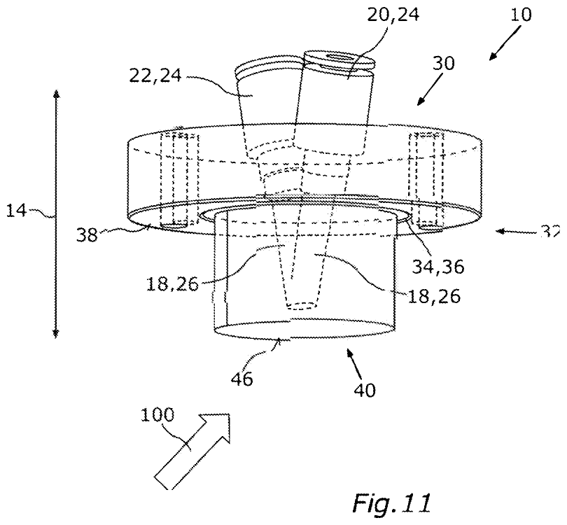

FIG. 11A semitransparent angled view of a tenth embodiment of an optical element according to the present invention, and

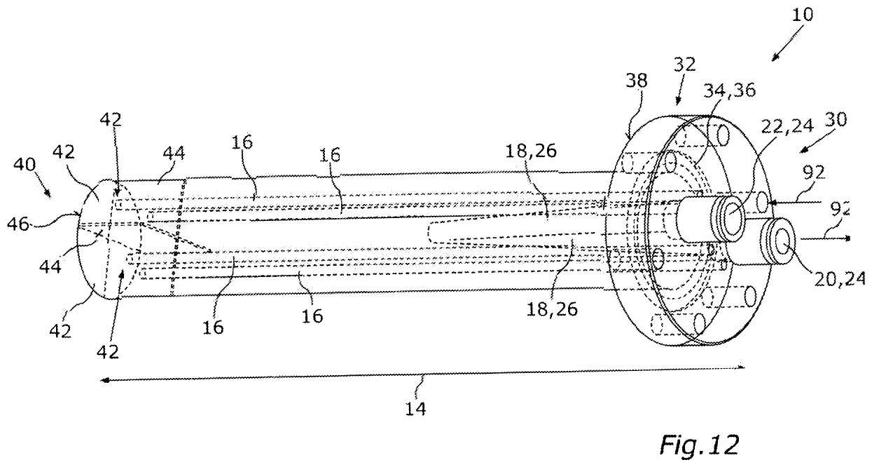

FIG. 12A semitransparent angled view of an eleventh embodiment of an optical element according to the present invention

FIG. 2 schematically depicts a possible embodiment of the optical element 10 according to the present invention, which is arranged at a flange 80 surrounding an opening 74 in a chamber wall 72 of a reaction chamber 70 according to the present invention. The reaction chamber 70 encloses a reaction volume filled with a reaction atmosphere 90, whereby outside of the reaction chamber 70 in most of the cases the ambient atmosphere 94 is present. However, the chamber wall 72 of the reaction chamber 70 can also completely or partly separate the reaction atmosphere 90 from another atmosphere different from the ambient atmosphere 94.

As clearly visible in FIG. 2, the central element of the optical element 10 is a one-piece body 12 comprising an ambient end 30 and a chamber end 40, which are arranged opposite to each other along a central body axis 14. Preferably, the one-piece body 12 consists of aluminum or of an aluminum alloy or of copper or of a copper alloy. In particular, in the depicted arranged state of the optical element, the chamber end 40 is arranged within the reaction chamber 70, the ambient end 30 respectively outside of the reaction chamber 70.

In particular, the ambient end 30 comprises a sealing means 32 for sealing the flange 80 of the reaction chamber 70. In the depicted example, the sealing means 32 form an elastomer seal comprising an elastomer ring seal 84, 88, whereby the sealing means 32 in particular provide a receptacle 36 for the elastomer ring seal 84, 88 and additionally a sealing surface 38.

At the opposite end of the one-piece body 12, the chamber end 46 carries an optical surface 46. In the depicted embodiment, the optical surface 46 is additionally coated with an optical coating 48 for an enhancement of reflectivity. This allows to effectively reflect an impinging electromagnetic radiation 100. As the optical surface 46 is provided as a planar surface, the reflection of the electromagnetic radiation 100 is provided as a specularly reflection.

The main advantage of the optical element 10 according to the present invention is due to the fact that the optical element 10 comprises the aforementioned one-piece body 12 which provides both the ambient end 30 and the chamber end 40. Thereby both the sealing means 32 and the optical surface 46 are arranged, positioned, and oriented with a fixed and in particular known relation to each other at the optical element 10 according to the present invention. Hence, by arranging the sealing means 32 at the flange 80 of the reaction chamber 70 according to the present invention, the position, orientation, and alignment not only of the ambient end 30 but also of the chamber end 40 of the optical element 10 according to the present invention is determined. Additional alignments of the optical surface 46 after the arrangement can thereby be avoided.

In the following, several variations of embodiments of the optical element 10 are described. All of them share the inventive concept of a one-piece body 12 comprising both the ambient end 30 and the chamber end 40 and hence the aforementioned advantages. Hence, in the following in particular the differences of the respective embodiments will be exposed. For the features shared by the different embodiments it will be referred in particular to the description above with respect to FIG. 2, even if not explicitly mentioned.

In contrast to the embodiment of the optical element 10 depicted in FIG. 2, the respective optical elements 10 of FIGS. 3 and 4 are intended for an absorption of the impinging electromagnetic radiation 100. However, said optical elements 10 of FIG. 3 and FIG. 4, respectively, provide different approaches for enhancing the respective absorption capability.

In the embodiment depicted in FIG. 3, the chamber end 40, and hence the optical surface 46 formed at the chamber end 40, is coated with an absorption coating 50. In contrast to that, FIG. 4 shows an optical element 10 with a roughened surface, for instance roughened by sand and/or bead blasting. Although shown for different embodiment, these measures also can be combined.

All other elements of the optical elements 10 depicted in FIGS. 3 and 4, in particular the one-piece body 12 forming the core of the optical element 10, are constructed similar to the embodiment shown in FIG. 2. Namely, for instance also said embodiments of FIGS. 3 and 4 comprise sealing means 32 provided at the ambient end 30 of the one-piece body 12. Hence, again the aforementioned advantage of a simplification of an alignment process can be provided.

The focus of the embodiment of the optical element 10 and of the reaction chamber 70, respectively, according to the present invention of FIG. 5 is on the sealing means 32. In Particular, the present sealing means 32 forms a part of a knife-edge type seal. A circumferential knife-edge 34 cuts deep into a metallic ring seal 84, 86 arranged in a circumferential receptacle 36 of the sealing means 32.

Circumferential sealing surfaces 38 complete the sealing means 32 and ensure the tight sealing of the opening 74 in the chamber wall 72 of the reaction chamber 70 (see FIG. 2). In particular, with such a knife-edge type seal, an ultra high vacuum of 10-12 hPa or lower can be achieved as reaction atmosphere 90 within the reaction chamber 70.

Again, for a description of all other elements, in particular of the optical surface 46 on the chamber end 40, please refer to the description above of the other embodiments of the optical element 10.

In FIG. 6 an embodiment of the optical element 10 and of the reaction chamber 70, respectively, according to the present invention is depicted, which comprises means for measuring 60, in particular means for measuring 60 of a temperature of the one-piece body 12. In particular, said means for measuring 60 can be provided as thermocouple. By measuring a temperature of the body 12, a measure of the energy deposited by the electromagnetic radiation 100 impinging onto the optical surface 46 into the body 12 can be provided. For that, a bore 16 is arranged starting at the ambient end 30 and extending into the body 12 and the means for measuring 60 is arranged within the bore 16, preferably at an inner end of the bore 16.

For electromagnetic radiation 100, which is to be reflected as depicted in FIG. 6, it is of advantage to measure the temperature as close to the optical surface 46 as possible. This holds also true for electromagnetic radiation 100, which is to be reflected (see FIG. 11). However, as an accidental melting of the chamber end 40 caused by the deposited energy of the electromagnetic radiation 100 cannot be completely excluded, a value of the extension of the bore 16 along the body axis 14 of around 75% to 95% or more was found suitable.

Again, for a description of all other elements, in particular of the optical surface 46 on the chamber end 40, please refer to the description above of the other embodiments of the optical element 10.

FIG. 7 shows another possible feature of the optical element 10 and the reaction chamber 70, respectively, according to the present invention, namely equipped with a cooling duct 18 arranged within the one-piece body 12. Said cooling duct 18 extends between an inlet opening 20 and an outlet opening 22, respectively, both of them arranged in the ambient end 30 of the body 12. This allows a coolant fluid 92 to flow through the body 12 and to remove excess energy caused by an absorption of electromagnetic radiation 100 impinging on the optical surface 46 of the chamber end. Preferably, the inlet opening 20 and the outlet opening 22 are threaded for an arrangement of screw-in terminals 24 (FIG. 11, 12) of supply lines of the coolant fluid 92.

The cooling ducts 18, and hence the optical element 10 can comprise means for measuring 60 a flow of the coolant fluid 92, and/or an absolute temperature of the coolant fluid 92, and/or a temperature change of the coolant fluid 92 between the inlet opening 20 and at the outlet opening 22. Hence the amount of cooling, and therefore the amount of energy deposited into the body 12 by the impinging electromagnetic radiation 100, can be measured.

In the embodiment depicted in FIG. 7, a reflection and/or shaping of the electromagnetic radiation 100 on the optical surface 46 is intended. For providing stable conditions, in particular with respect to the temperature of the body 12 in the vicinity of the optical surface 46, it is of advantage that the maximum extension of the cooling duct 18 along the body axis 14 is at least 60%, preferably 75%, most preferably 85% or more, of the extension of the body 12 along the body axis 14 from the ambient end 30 towards the chamber end 40.

In the opposite case, namely if the optical surface 46 is designed to absorb the impinging electromagnetic radiation 100, this can be counterproductive, in particular for embodiments with a simultaneous temperature measurement of the body 12 (see in particular FIG. 12 and the accompanied description). Hence, for these embodiments, a maximum extension of the cooling duct 18 along the body axis 14 of between 20% and 65%, preferably between 35% and 55%, of the extension of the body 12 along the body axis 14 from the ambient end 30 towards the chamber end 40 is preferred to allow for sufficient temperature variation and measurement accuracy of the measured temperature with the amount of absorbed electromagnetic radiation 100.

In FIG. 8 a further enhancement of the reaction chamber 70 according to the present invention is depicted. Namely, in this embodiment the flange 80 of the reaction chamber 70 comprises a flange rim 82 connected by a bellow 76 to the chamber wall 72 of the reaction chamber 70. The optical element 10 according to the present invention is arranged with its sealing means 32 at this rim 82.

As depicted in FIG. 8, the bellow 76 allows a certain movement of the rim 82 and hence also of the optical element 10 arranged and fixed to said rim 82. As a result, an alignment of the position and/or orientation of the optical surface 46 on the chamber end 40 of the optical element 10 can be provided by aligning the ambient end 30 of the optical element 10 and hence as a whole more easily.

In particular, the reaction chamber 70, for instance the optical element 10, according to the present invention can further comprise means for adjusting 78 the relative position of the optical surface 46 of the optical element 10 within the reaction chamber 70 by moving the optical element 10 within the range of movement provided by the bellow 76. Said means for adjusting 78 can be preferably fixed to the chamber wall 72 and moves the ambient end 30 of the optical element 10 (as depicted in FIG. 8) or alternatively the rim 82. A vice-versa arrangement with a fixation of the means for adjusting 78 on the optical element 10 or the rim 82 and a movable support on the chamber wall 72, provides the same advantages.

In addition, and as depicted in FIG. 9, the optical element 10 and the reaction chamber 70, respectively, according to the present invention can also be equipped with a feedthrough 64 connecting the chamber end 30 with the ambient end 40. Sealing means for sealing the opening of the feedthrough 64 are provided but not shown and referenced, respectively, in FIG. 9, said feedthroughs 64 are used for providing electrical connections and/or fluid connections from the ambient end 30 to the chamber end 40.

In particular, the one-piece body 12 can also comprise attachment means 62 on the chamber end 40 for attaching and/or fixing additional components within the reaction chamber 70. Especially for embodiments with said attachment means 62, a respective feedthrough 64 can be used for providing the necessary electrical and/or fluid connections for the additional component attached and/or fixed to the attachment means 62.

FIGS. 10 to 12 show semitransparent angled views of three different embodiments of the optical element 10 according to the present invention, the first two of them intended for reflection of electromagnetic radiation 100 on the optical surface 46, the last one intended for absorption of the electromagnetic radiation 100. All three embodiments of the optical element 10 comprise a cooling duct 18 which is V-shaped. Two straight legs 26 extend from the inlet opening 20 and the outlet opening 22, respectively, into the one-piece body 12 of the respective optical element 10 and meet within the body 12 for forming the continuous cooling duct. The embodiments of FIG. 11, 12 further comprise terminals 24 arranged at the inlet opening 20 and the outlet opening 22, respectively, for an easy and convenient connection of the respective cooling duct 18 to a supply line of the coolant fluid 92.

In addition, in all three embodiments of the shown optical elements 10, the sealing means 32 comprise a receptacle 36 and sealing surfaces 38 and additionally a knife-edge 34 of a knife-edge type seal.

FIG. 10 depicts an optical element 10, the optical surface 46 of which on the chamber end 40 is tilted with respect to the body axis 14, in particular by an angle of 45°. Preferably, the optical element 10 can be used for reflecting electromagnetic radiation 100 between directions parallel to the body axis 14 of the body 12 of the optical element 10 and normal to this body axis 14. The one-piece body 12 can preferably be manufactured from a high-strength aluminum alloy such as EN AW 6082 T6. Additionally, the optical surface 46 can be machined with diamond tools to a smooth mirror finish, avoiding the need further coating.

In contrast to the embodiment described in the previous paragraph, FIG. 11 shows an optical element 10 with an optical surface 46 perpendicular to the body axis 14 and hence parallel to the orientation of the flange 80 (not shown, see for instance FIG. 2). This allows a shorter overall design of the optical element 10 in comparison to the embodiment with the tilted optical surface 46 described in the previous paragraph with respect to FIG. 10. In addition, the cooling duct 18 can now be brought into closer proximity to the center of the optical surface 46, and hence to the point with the highest electromagnetic power density of the impinging electromagnetic radiation 100. Further, the higher symmetry of this geometry leads to a more symmetric temperature distribution on the optical surface 46. This in turn reduces possible low symmetry distortions of the reflected beam due to nonuniform thermal expansion of the optical surface 46 under high loads.

FIG. 12 shows an optical element 10 according to the invention which acts as an absorber with bolometer functionality. In contrast to the embodiments described with respect to FIG. 10, 11, the optical surface 46 on the chamber end 40 is now roughened by sand blasting or bead blasting to maximize its absorption. The cooling duct 18 ends around the middle of the extension of the one-piece body 12 along its body axis 14, in particular a significant distance away from the optical surface 46. This produces a thermal gradient between the absorbing optical surface 46 and the cooling duct 18 that transports the heat away, leading to elevated temperatures even at some distance from the optical surface 46 in the direction of the body axis 14.

Four long, thin bores 16 reach down to this region of elevated temperature, allowing the insertion of thin means for measuring 60 the temperature (not shown), preferably thermocouple contacts, that measure the temperatures at the ends of these four bores 16. At the same time, the ends of the bores 16 are far enough away from the absorbing optical surface 46 that there is some safety distance in case of an overloading of the optical element 10 with a melting of the material of the one-piece body 12 close to the optical surface 46 where the electromagnetic beam is absorbed. The thin bores 16 preferably are 4 mm in diameter to allow for a variety of different temperature sensors to be used alternatively.

Such a setup acts as a bolometer, allowing the measurement of the absorbed radiation intensity via the temperature close to the absorbing optical surface 46, while maintaining the ambient end 30 of the device at cooling water temperature.

In addition, one may measure the volume flow per time unit of coolant fluid 92, in our case cooling water, and the temperature difference between the coolant fluid 92 at the inlet opening 20 and at the outlet opening 22, respectively, to quantitatively determine the absorbed power.

In addition, the depicted optical element 10 has slots in the optical surface 46 on the chamber end 40, dividing the absorbing optical surface 46 into four end segments 42 of equal size. With each end segment 42 being equipped with a means for measuring 60 the temperature arranged in an own bore 16 at symmetry equivalent positions, the distribution of the absorbed radiation energy between these four end segments 42 may be determined.

This allows the spatially resolved detection of the beam position of the electromagnetic radiation 100 impinging on the optical surface 46. With equal energies absorbed in all four end segments 42, and therefore equal temperatures measured by all four thermocouple sensors 60, the beam is centered on the device. Any deviations from this equilibrium yield information about the directions of the deviations and can therefore be used to steer the beam of the electromagnetic radiation 100 and to reposition it to the center of the optical element 10.

### LIST OF REFERENCES

10 Optical element
12 Body
14 Body axis
16 Bore
18 Cooling duct
20 Inlet opening
22 Outlet opening
24 Terminal
26 Leg
30 Ambient end
32 Sealing means
34 Knife-edge
36 Receptacle
38 Sealing surface
40 Chamber end
42 End segment
44 Slot
46 Optical surface
48 Optical coating
50 Absorption coating
60 Means for measuring
62 Attachment means
64 Feedthrough
70 Reaction chamber
72 Chamber wall
74 Opening
76 Bellow
78 Means for adjusting
80 Flange
82 Rim
84 ring seal
86 Metallic ring seal
88 Elastomer ring seal
90 Reaction atmosphere
92 Coolant fluid
94 Ambient atmosphere
100 Electromagnetic radiation
200 Reflector section
202 Cooling tube
204 Weld
206 Seal section

1-25. (canceled)

26. Optical element for use with a reaction chamber, the reaction chamber having a chamber wall, with a flange of the reaction chamber being arranged at an opening in the chamber wall,
wherein the optical element comprises a one-piece body with an ambient end and a chamber end arranged opposite to each other along a central body axis, whereby in an assembled state of the optical element the ambient end is arranged outside of the reaction chamber and the chamber end is arranged within the reaction chamber,
whereby the ambient end of the body comprises a sealing means for sealing the flange of the reaction chamber, and
whereby the chamber end comprises an optical surface for reflecting and/or shaping and/or absorbing an electromagnetic radiation within the reaction chamber.

27. Optical element according to claim 26,
wherein
the body consists of aluminum or of an aluminum alloy or of copper or of a copper alloy.

28. Optical element according to claim 26,
wherein
the sealing means forms a part of a knife-edge type seal.

29. Optical element according to claim 26,
wherein
the sealing means forms a part of an elastomer seal.

30. Optical element according to claim 26,
wherein
the chamber end comprises a planar surface forming at least a part of the optical surface for specularly reflecting an impinging electromagnetic radiation.

31. Optical element according to claim 26,
wherein
the chamber end comprises a curved surface forming at least a part of the optical surface for reflecting and simultaneously shaping an impinging electromagnetic radiation.

32. Optical element according to claim 30,
wherein
the planar surface and/or the curved surface consists of a bare surface of the body.

33. Optical element according to claim 30,
wherein
the planar surface and/or the curved surface are coated with an active optical coating chosen for the intended electromagnetic radiation to be reflected.

34. Optical element according to claim 26,
wherein
the chamber end comprises a roughened surface and/or a surface coated with an absorption coating for absorbing an impinging electromagnetic radiation.

35. Optical element according to claim 34,
wherein
the chamber end is slotted in two or more end segments by slots perpendicular to the body axis.

36. Optical element according to claim 35,
wherein
the slots extend 5% to 50% of the length of the body along the body axis from the chamber end towards the ambient end.

37. Optical element according to claim 26,
wherein
the body comprises one or more continuous cooling ducts for a coolant fluid, wherein each cooling duct comprises an inlet opening and an outlet opening arranged at the ambient end of the body.

38. Optical element according to claim 37,
wherein
the inlet opening and the outlet opening are threaded for an arrangement of screw-in terminals of supply lines of the coolant fluid.

39. Optical element according to claim 37,
wherein
the one or more cooling ducts are V-shaped, wherein from both the inlet opening and the outlet opening, respectively, a straight leg of the cooling duct extends into the body, whereby the two legs meet within the body.

40. Optical element according to claim 37,
wherein
if the optical surface is designed to reflect and/or shape the impinging electromagnetic radiation, the maximum extension of the cooling duct along the body axis is at least 60% of the extension of the body along the body axis from the ambient end towards the chamber end.

41. Optical element according to claim 37,
wherein
if the optical surface is designed to absorb an impinging electromagnetic radiation, the maximum extension of the cooling duct along the body axis is between 20% and 65% of the extension of the body along the body axis from the ambient end towards the chamber end.

42. Optical element according to claim 37,
wherein
the one or more cooling ducts are equipped with means for measuring a flow of the coolant fluid, and/or with means for measuring an absolute temperature of the coolant fluid, and/or with means for measuring a temperature change of the coolant fluid between the inlet opening and at the outlet opening.

43. Optical element according to claim 26,
wherein
the body comprises one or more bores for arranging a means for measuring a temperature of the body, wherein the one or more bores start at the ambient end of the body and end within the body along the body axis at least at 75% of the extension of the body along the body axis from the ambient end towards the chamber end.

44. Optical element according to claim 43,
wherein
the body comprises a bore for each of the end segments, wherein the respective bore ends within the respective end segment.

45. Optical element according to claim 26,
wherein
the body comprises attachment means on its chamber end for attaching and/or fixing additional components within the reaction chamber.

46. Optical element according to claim 26,
wherein
the body comprises one or more feedthroughs for providing electrical connections and/or fluid connections from the ambient end to the chamber end.

47. Optical element according to claim 45,
wherein
the one or more feedthroughs end at the attachment means for providing electrical connections and/or fluid connections for the additional component arrangeable and/or fixable at the attachment means.

48. Reaction chamber, comprising a chamber wall enclosing a sealable reaction volume, the reaction volume fillable with a reaction atmosphere, the reaction chamber further comprising a flange arranged at an opening in the chamber wall, wherein
an optical element according to claim 26 is arranged at the flange and seals the opening in the chamber wall.

49. Reaction chamber according to claim 48,
wherein
the flange comprises a flange rim for arranging the optical element, whereby the flange rim is connected by a bellow to the chamber wall.

50. Reaction chamber according to claim 49,
wherein
the reaction chamber comprises a means for adjusting the relative position of the optical surface of the optical element within the reaction chamber by moving the optical element within the radius of movement provided by the bellow.
